(19) United States
(12) Patent Application Publication
(10) Pub. No.: US 2022/0418080 A1
(43) Pub. Date: Dec. 29, 2022

(54) ACTIVE COOLING STORAGE DEVICE

(71) Applicant: TEAM GROUP INC., New Taipei City (TW)

(72) Inventors: Hsun Chia MA, New Taipei City (TW); Tzu Hsien CHUANG, New Taipei City (TW); Kuan Ting CHEN, New Taipei City (TW)

(73) Assignee: TEAM GROUP INC., New Taipei City (TW)

(21) Appl. No.: 17/385,759

(22) Filed: Jul. 26, 2021

(30) Foreign Application Priority Data
Jun. 29, 2021 (TW) 110123741

(51) Int. Cl. H05K 1/02; H05K 7/20

(52) U.S. Cl. CPC H05K 1/0203; H05K 7/2039; H05K 2201/10159

(57) ABSTRACT

Disclosed is an active cooling storage device comprising: a memory having memory chips; a thermal pad attached to the memory chips; a heat dissipater having a heat sink and a metal base, a receiving concave being provided between the heat sink and the metal base, the metal base being contacted with a bottom surface of the heat sink an upper surface of the thermal pad; a thermoelectric cooler, which is disposed within the receiving concave in such a manner that a cold side of the thermoelectric cooler facing an upper surface of at least one of the memory chips and facing toward the metal base, and a hot side of the thermoelectric cooler facing toward the heat sink; and a cooler controller, which receives a memory temperature value of the memory, and controlling the thermoelectric cooler to be activated when the memory temperature value is higher than a threshold temperature value.

### FIELD OF THE INVENTION

The present invention relates to a storage device, and more particularly relates to an active cooling storage device.

### BACKGROUND OF THE INVENTION

With the increase of accessing speed and transmitting speed of the storage devices, it causes a problem of overheating, which can not be ignored. A large amount of heat, generated by frequent and long-term access of the storage device, concentrating on small chips will cause overheating for the chips to trigger the protection mechanism, and thus it results in performance degradation or even a lifespan shortened.

In order to solve the problem of overheating, the conventional storage devices apply passive cooling, which is generally implemented by using a heat sink to dissipate heat through air. However, the cooling efficiency of the passive cooling leaves much to be desired. It is often necessary to dispose multiple fans inside a crowded computer case to achieve a certain degree of cooling effect.

### SUMMARY OF THE INVENTION

Accordingly, one objective of the present invention is to provide an active cooling storage device, which has better cooling effect than that of a storage device only using a heat sink.

In order to overcome the technical problems in prior art, the present invention provides an active cooling storage device, comprising: a memory, having a circuit board and a plurality of memory chips on the circuit board; a thermal pad, attached to the plurality of memory chips; a heat dissipater, having a heat sink and a metal base, a bottom surface of the heat sink having a heat-dissipating contact surface, a receiving concave being provided between the heat sink and the metal base, the heat-dissipating contact surface being contacted with an upper surface of the metal base, and a bottom surface of the metal base being contacted with an upper surface of the thermal pad; a thermoelectric cooler, which is disposed within the receiving concave in such a manner that the metal base and the thermal pad are disposed between the thermoelectric cooler and the plurality of memory chips, a cold side of the thermoelectric cooler facing an upper surface of at least one of the plurality of memory chips and facing toward the metal base, and a hot side of the thermoelectric cooler facing toward the heat sink; and a cooler controller, which is connected to the thermoelectric cooler to control the thermoelectric cooler, the cooler controller receiving a memory temperature value of the memory chips, and controlling the thermoelectric cooler to be activated when the memory temperature value is higher than a threshold temperature value.

In one embodiment of the present invention, the memory is a solid-state drive, at least one of the plurality of memory chips is a SSD controller, and the cold side of the thermoelectric cooler faces toward an upper surface of the SSD controller.

In one embodiment of the present invention, the memory is a main memory.

In one embodiment of the present invention, the cooler controller is disposed on the circuit board.

In one embodiment of the present invention, the cooler controller is connected to a computer terminal, and the memory temperature value of the memory is received from the computer terminal.

In one embodiment of the present invention, the memory is provided with a temperature sensor, the cooler controller is connected to the temperature sensor to receive the memory temperature value.

By the technical means adopted by the present invention, the cooler controller controls the thermoelectric cooler to be activated to switch from the passive cooling to the active cooling when the memory temperature value is higher than a threshold temperature value. When the memory temperature value of the memory drops below the threshold temperature value, the cooler controller controls the thermoelectric cooler to be deactivated. Therefore, the active cooling storage device of the present invention can provide relatively high cooling efficiency when the cooling demand is high, and can provide relatively low energy consumption when the cooling demand is low.

### BRIEF DESCRIPTION OF THE DRAWINGS

FIG. 1 is a schematic view illustrating an active cooling storage device according to a first embodiment of the present invention;

FIG. 2 is a schematic exploded view illustrating the active cooling storage device according to the first embodiment of the present invention;

FIG. 3 is schematic exploded view illustrating the active cooling storage device according to the first embodiment of the present invention from another viewpoint;

FIG. 4 is a schematic side cross-section view illustrating the active cooling storage device according to the first embodiment of the present invention.

FIG. 5 is a schematic side cross-section view illustrating an active cooling storage device according to a second embodiment of the present invention.

FIG. 6 is a schematic side cross-section view illustrating an active cooling storage device according to a third embodiment of the present invention.

### DETAILED DESCRIPTION OF THE PREFERRED EMBODIMENTS

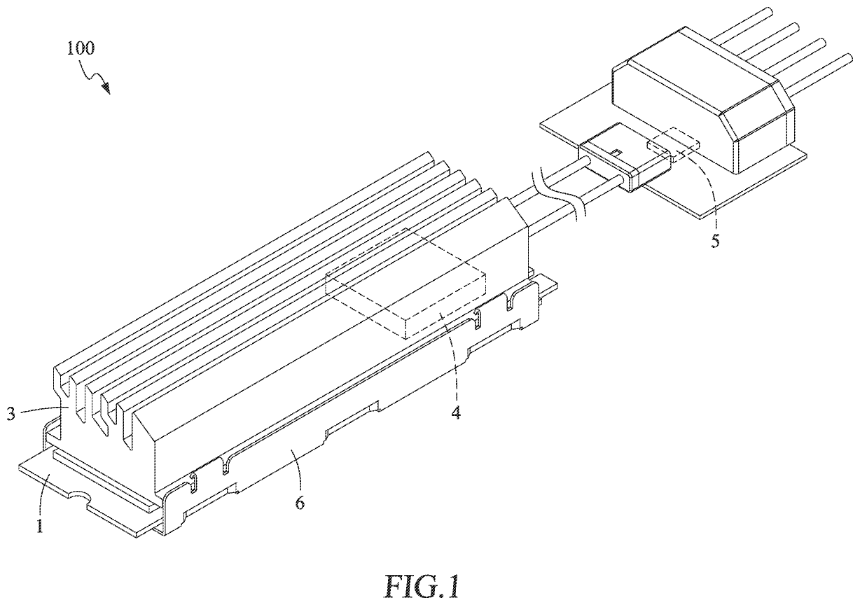

The preferred embodiments of the present invention are described in detail below with reference to FIG. 1 to FIG. 6. The description is used for explaining the embodiments of the present invention only, but not for limiting the scope of the claims.

As shown in FIG. 1 to FIG. 3, an active cooling storage device 100 according to first embodiment of the present invention includes: a memory 1, a thermal pad 2, a heat dissipater 3, a thermoelectric cooler 4, and a cooler controller 5.

The memory 1 has a circuit board 11 and a plurality of memory chips 12. The plurality of memory chips 12 is disposed on one side or both sides of the circuit board 11. In this embodiment, the memory 1 is a solid-state drive. The memory chips 12 of the solid-state drive include a flash memory 13 and a SSD controller 14. Alternatively, in other embodiments, the memory 1 may be a main memory.

The thermal pad 2 is attached to the plurality of memory chips 12. In detail, the thermal pad 2 is attached to all memory chips 12 which are disposed on one side of the circuit board 11 to evenly transfer and dissipate heat of all of the memory chips 12. In this embodiment, the thermal pad 2 is a silicone sheet. The heat of the memory chip 12 attached with the thermal pad 2 can be quickly conducted away by high thermal conductivity coefficient of silicone. In addition, the thermal pad 2 is a soft material and thereby can be attached to each one of the memory chips 12 in an adaptive manner even if the heights of the memory chips 12 are different. The thermal pad 2 is an insulating material that prevents the electric current from flowing through the thermal pad 2 and causing interference to electronic components. In other embodiment, the thermal pad 2 may be a hard material with high thermal conductivity coefficient.

The heat dissipater 3 has a heat sink 31 and a metal base 32. A bottom surface of the heat sink 31 has a heat-dissipating contact surface 311. A receiving concave 33 is provided between the heat sink 31 and the metal base 32. The heat-dissipating contact surface 311 is contacted with an upper surface of the metal base 32, and a bottom surface of the metal base 32 is contacted with an upper surface of the thermal pad 2.

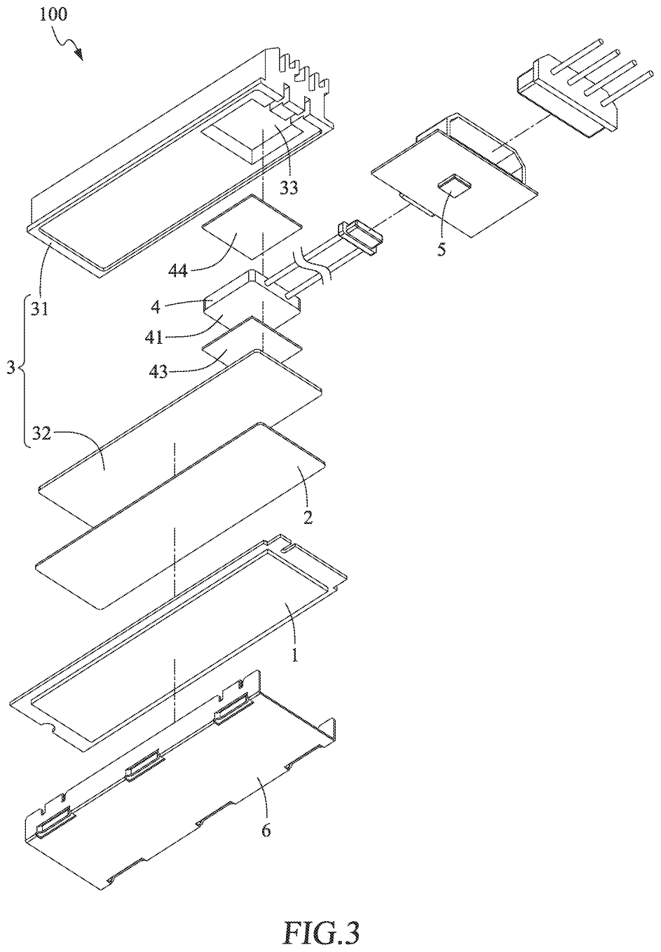

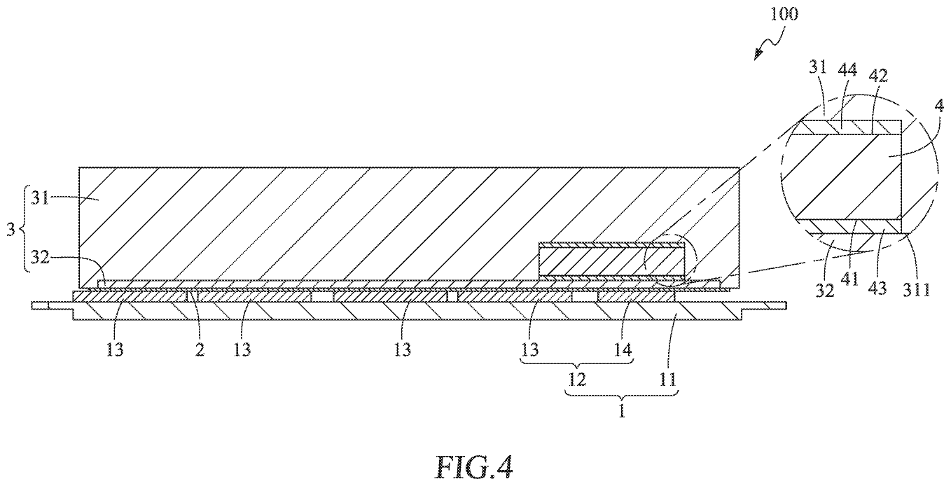

As shown in FIG. 3 and FIG. 4, the thermoelectric cooler 4 is disposed within the receiving concave 33. In the present invention, the receiving concave 33 is a concave hole at the bottom surface of the heat sink 31 to cover the upper surface and the whole side surface of the thermoelectric cooler 4 in such a manner that the thermoelectric cooler 4 is embedded in the heat sink 31. It goes without saying that the present invention is not limited to this, and the receiving concave 33 may be a notch to cover a part of the side surface of the thermoelectric cooler 4.

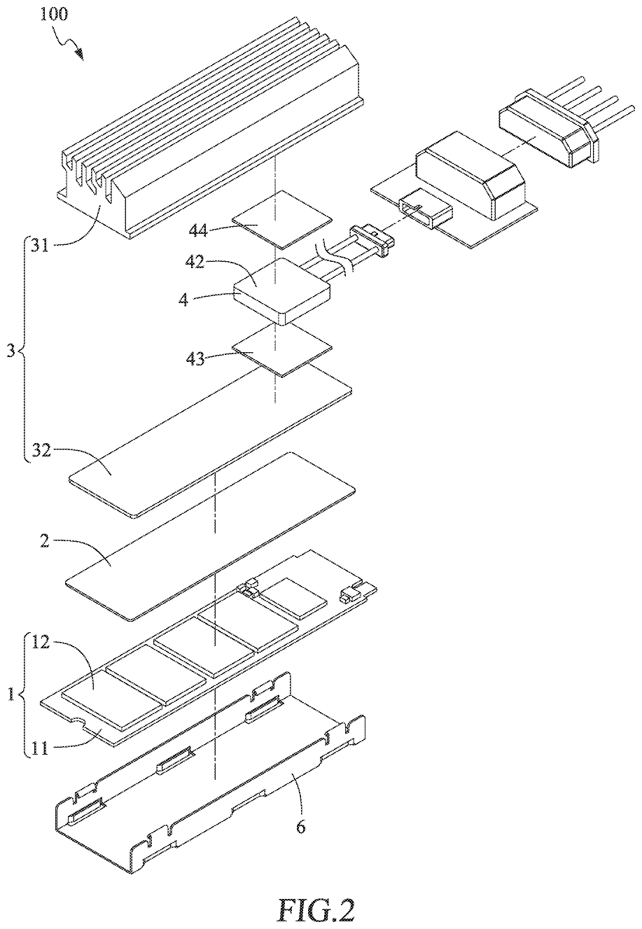

As shown in FIG. 2 to FIG. 4, the thermoelectric cooler 4 is disposed within the receiving concave 33 in such a manner that the metal base 32 of the heat dissipater 3 and the thermal pad 2 are disposed between the thermoelectric cooler 4 and the plurality of memory chips 12. A cold side 41 of the thermoelectric cooler 4 faces an upper surface of at least one of the plurality of memory chips 12 and faces toward the metal base 32, and a hot side 42 of the thermoelectric cooler 4 faces toward the heat sink 31. Thereby, the heat of the metal base 32 is transferred to the heat sink 31 through the thermoelectric cooler 4, and the metal base 32 is cooled by the thermoelectric cooler 4.

A cold side thermal pad 43 and a hot side thermal pad 44 are provided at the cold side 41 and the hot side 42 of the thermoelectric cooler 4 respectively so as to enhance the heat conduction efficiency between the metal base 32 and the thermoelectric cooler 4 and the heat conduction efficiency between the thermoelectric cooler 4 and the heat sink 31.

In this embodiment, the memory 1 is a solid-state drive.

When the solid-state drive is operating, the temperature of the SSD controller 14 would be higher than the temperature of the flash memory 13. The thermoelectric cooler 4 faces the upper surface of the SSD controller 14 and overlaps the SSD controller 14 to cool down the hottest components of the memory 1. The thermoelectric cooler 4 only overlaps with the SSD controller 14 and does not overlap with the flash memory 13 to achieve the best efficiency per unit area of the thermoelectric cooler 4. Of course, in other embodiments, the thermoelectric cooler 4 overlaps not only the SSD controller 14, but also overlaps with at least one flash memory 13 at the same time, so as to achieve a higher overall cooling effect.

As shown in FIG. 3, a cooler controller 5 is connected to the thermoelectric cooler 4 to control the thermoelectric cooler 4. The cooler controller 5 receives a memory temperature value of the memory 1. When the memory temperature value is higher than a threshold temperature value, the cooler controller 5 controls the thermoelectric cooler 4 to be activated, so as to switch from the passive cooling to the active cooling. When the memory temperature value drops below the threshold temperature value, the cooler controller 5 controls the thermoelectric cooler 5 to be deactivated. Thereby, the active cooling storage device of the present invention can provided relatively high cooling efficiency when the cooling demand is high, and can provide relatively low energy consumption when the cooling demand is low.

As shown in FIG. 3, in this embodiment, the cooler controller 5 is disposed to be separated from the circuit board 11 of the memory 1. In other embodiments, the control unit 5 may be disposed on the circuit board 11 and be integrated with the memory 1.

The cooler controller 5 is connected to a computer terminal, and the memory temperature value is received from the computer terminal. The cooler controller 5 also receives the power from the computer terminal to control the power to be supplied to the thermoelectric cooler 4. In other embodiments, the cooler controller 5 is connected to the temperature sensor of the memory 1 to receive the memory temperature value without transmitting memory temperature value through the computer terminal.

In this embodiment, in the active cooling storage device 100, the memory unit 1 and the heat dissipation unit 3 are fixed to each other through a fixture 6.

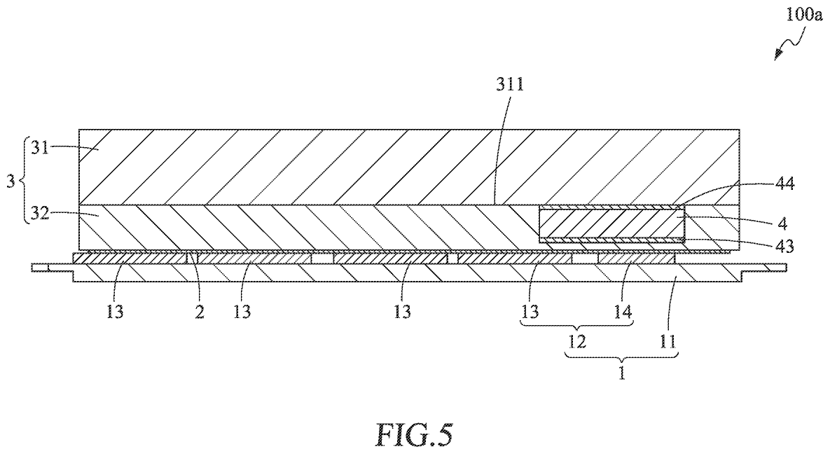

As shown in FIG. 5, according to the second embodiment of the present invention, the structure of an active cooling storage device 100a is approximately the same as that of the active cooling storage device 100 of the first embodiment. The main difference therebetween is that the receiving concave 33 is provided at the top surface of the metal base 32 to cover the lower surface and the whole side surface of the thermoelectric cooler 4 in such a manner that the thermoelectric cooler 4 is embedded in the metal base 32.

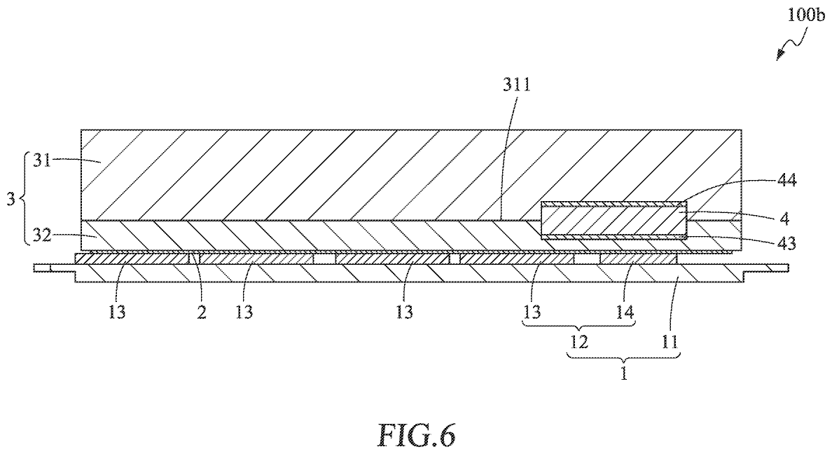

As shown in FIG. 6, according to the third embodiment of the present invention, the structure of an active cooling storage device 100b is approximately the same as that of the active cooling storage device 100 of the first embodiment. The main difference therebetween is that the receiving concave 33 is provided at the bottom surface of the heat sink 31 and at the top surface of the metal base 32 in such a manner that a portion of the thermoelectric cooler 4 is embedded in the heat sink 31 and another portion of the thermoelectric cooler 4 is embedded in the metal base 32.

The above description should be considered as only the discussion of the preferred embodiments of the present invention. However, a person having ordinary skill in the art may make various modifications without deviating from the present invention. Those modifications still fall within the scope of the present invention.

What is claimed is:

1. An active cooling storage device, comprising:
a memory, having a circuit board and a plurality of memory chips on the circuit board;
a thermal pad, attached to the plurality of memory chips;
a heat dissipater, having a heat sink and a metal base, a bottom surface of the heat sink having a heat-dissipating contact surface, a receiving concave being provided between the heat sink and the metal base, the heat-dissipating contact surface being contacted with an upper surface of the metal base, and a bottom surface of the metal base being contacted with an upper surface of the thermal pad;
a thermoelectric cooler, which is disposed within the receiving concave in such a manner that the metal base and the thermal pad are disposed between the thermoelectric cooler and the plurality of memory chips, a cold side of the thermoelectric cooler facing an upper surface of at least one of the plurality of memory chips and facing toward the metal base, and a hot side of the thermoelectric cooler facing toward the heat sink; and
a cooler controller, which is connected to the thermoelectric cooler to control the thermoelectric cooler, the cooler controller receiving a memory temperature value of the memory, and controlling the thermoelectric cooler to be activated when the memory temperature value is higher than a threshold temperature value.

2. The active cooling storage device of claim 1, wherein the memory is a solid-state drive, at least one of the plurality of memory chips is a SSD controller, and the cold side of the thermoelectric cooler faces toward an upper surface of the SSD controller.

3. The active cooling storage device of claim 1, wherein the memory is a main memory.

4. The active cooling storage device of claim 1, wherein the cooler controller is disposed on the circuit board.

5. The active cooling storage device of claim 1, wherein the cooler controller is connected to a computer terminal, and the memory temperature value of the memory is received from the computer terminal.

6. The active cooling storage device of claim 1, wherein the memory is provided with a temperature sensor, the cooler controller is connected to
the temperature sensor to receive the memory temperature value.
